(19) United States
(12) Patent Application Publication
(10) Pub. No.: US 2011/0167690 A1
(43) Pub. Date: Jul. 14, 2011

(54) Light-Emitting Device

(76) Inventors: Asgeir Bjarnason, Wing Lok Street Central (HK); Kristjan Arnthorsson, Hong kong (HK)

(21) Appl. No.: 13/120,252

(22) PCT Filed: Sep. 23, 2009
(86) PCT No.: PCT/IB2009/054172

§ 371 Date: Mar. 22, 2011

(30) Foreign Application Priority Data
Sep. 23, 2008 (GB) 0817352.8

(51) Int. Cl. G09F 13/16; F21V 7/00; F21V 9/00; F21V 7/07; G09F 7/04; H05K 13/00

(52) U.S. Cl. 40/582; 362/296.01; 362/235; 362/231; 362/296.05; 29/592.1

(57) ABSTRACT

The present invention relates to the fields of illuminated signs and displays, and to decorative and specialist lighting fixtures. A light transmissive device (1) includes a panel (2) having a cavity (4) for housing a light source (6), the panel having surfaces such that light emitted from a light source (6) in the cavity (4) propagating along the panel (2) will be substantially totally internally reflected. The invention provides a construction that allows for a slim lighting panel with an innovative feature in the form of an illuminated edge at the sides of the light transmissive device, of any colour, thus providing a display device with a high visual impact.

### BACKGROUND

a. Field of the Invention

The present invention relates to the fields of illuminated signs and displays, and to decorative and specialist lighting fixtures.

b. Related Art

Illuminated displays or signs are commonly used to illuminate advertisements or images. Similar light-emitting devices are also used as decorative lights, for example recessed ceiling lights, or in the form of a light-box for viewing transparencies.

One type of illuminated display is known as an edge lit display. These displays have a light source directed to the edge of a light transmissive panel, and conventionally a cover is required to enclose both the panel and the light source. The need for this cover makes the displays both impractical and aesthetically unpleasant in some desired uses.

### SUMMARY OF THE INVENTION

Aspects of the invention are specified in the independent claims. Preferred features are specified in the dependent claims.

### BRIEF DESCRIPTION OF THE DRAWINGS

The invention will now be further described, by way of example only, and with reference to the accompanying drawings, in which:

FIG. 1 is a perspective view of a light transmissive device according to a preferred embodiment of the invention;

FIG. 2 is a perspective view of a light-emitting device showing light transmitting sheets and edge covering according to one embodiment of the invention;

FIG. 3 is a partial cross-sectional view of one embodiment of a light-emitting device showing location of a light source;

FIG. 4 is a partial cross-sectional view of one embodiment of a light-emitting device, showing the arrangement of a light transmissive device, two light transmitting sheets and an edge covering. This edge covering can be applied with inks or similar;

FIGS. 5 and 6 are partial cross-sectional views of a light-emitting device showing alternative light sources;

FIG. 7 is a partial cross-sectional view of a light-emitting device showing an alternative cavity to contain a light source;

FIG. 8 is a partial cross-sectional view of a light transmissive device showing the incorporation of a reflection strip in a further embodiment of the invention;

FIGS. 9 and 10 are partial cross-sectional views of light-emitting devices showing alternative edge coverings according to further embodiments of the invention;

FIG. 11 is a perspective view of a light-emitting device showing the position of magnetic attachment means according to one embodiment of the device;

FIG. 12 is a partial cross-sectional view of a light-emitting device showing magnetic and metal plates for attaching light transmitting sheets to both faces of a light transmissive panel in one embodiment of the invention.

### DETAILED DESCRIPTION

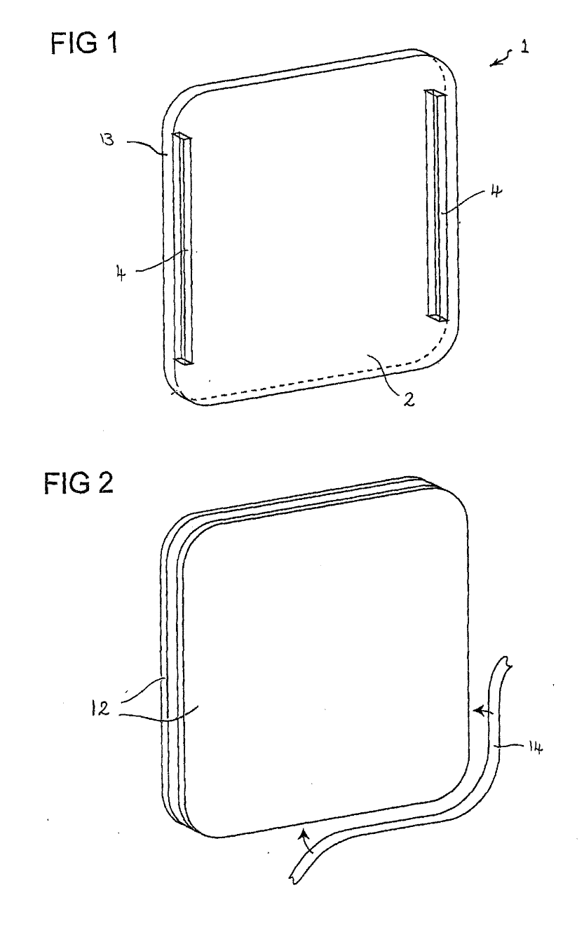

FIG. 1 shows a light transmissive device 1 including a substantially rectangular light transmissive panel 2. In a preferred embodiment the panel 2 has a slim profile, so that the thickness of the panel 2 is much less than the width or length. The panel 2 comprises cavities 4 to house an appropriate light source 6. The cavities 4 may extend fully (FIG. 7) or only partially through the thickness of the panel 2. The cavities 4 may be formed by moulding, drilling, cutting, etching, routing or by any other appropriate means.

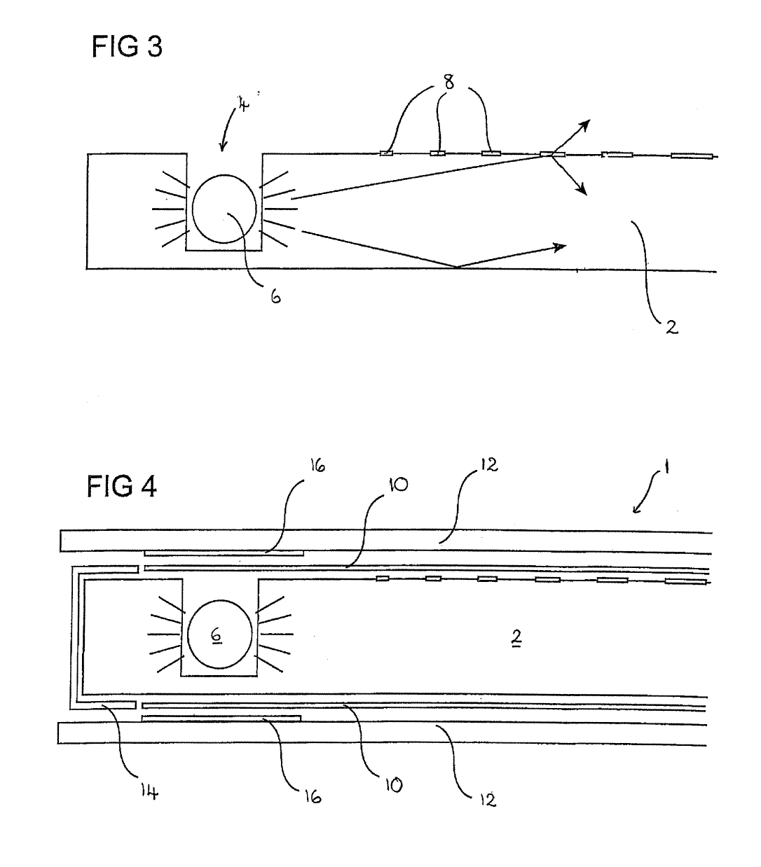

The panel is made from an appropriate material such that light emitted from a light source in the cavity 4 propagating along the panel will be substantially internally reflected. One or both faces, or major surfaces, of the light transmissive panel 2 are patterned 8 or treated to produce regions of the surface that allow light to be emitted from the surface of the panel, as shown in FIG. 3. The patterning 8 on the faces of the panel 2 may be in the form of v-cut grooves, laser-etched areas, a printed pattern or similar. In a preferred embodiment the patterning 8 is in the form of dots or lines. The arrangement of the patterned 8 or treated regions on the face of the panel 2 is such that the light emitted from the panel is essentially even over the face of the panel. The result is that the entire panel acts as a substantially even light source.

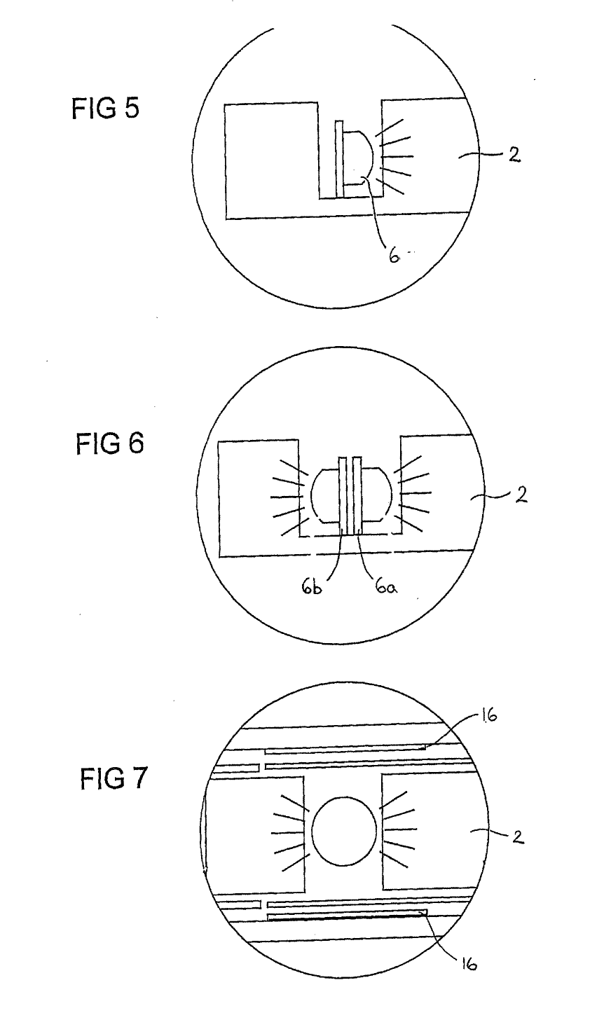

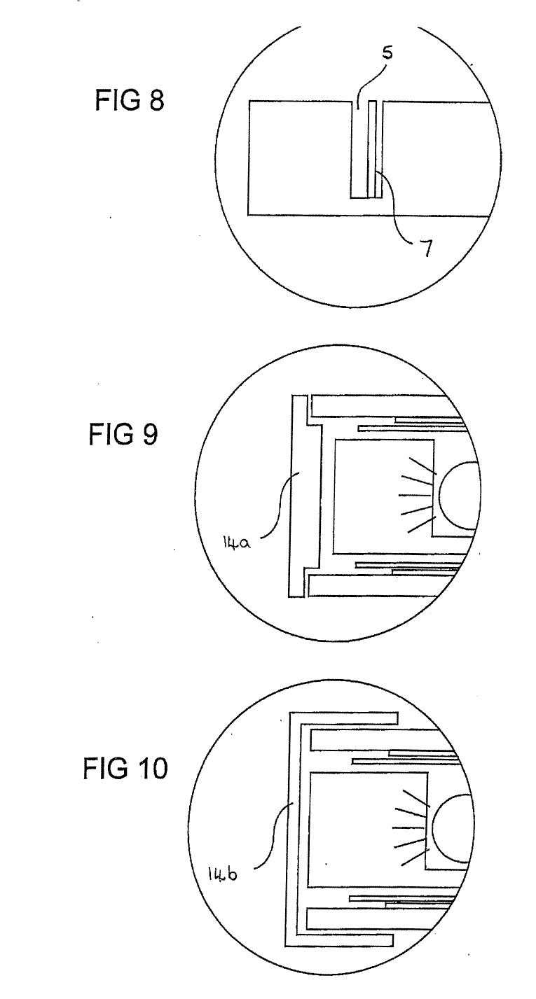

A light source 6 housed within a cavity 4 may be any suitable light source, and may be light emitting diodes (LEDs) or linear fluorescent lamps. Furthermore, the light source may be designed to emit light only towards the centre of the light transmissive panel 2, as shown in FIG. 5. In one embodiment, the light source may comprise one lamp 6a emitting light towards the centre of the panel 2, and a second lamp 6b emitting light towards the edge of the panel 2, as shown in FIG. 6. The lamps 6a and 6b may be chosen to be different colours or different types. Additionally, the light source 6 may be programmed by a controller (not shown) to switch on and off to produce a desired lighting effect.

The edges 13 of the panel 2 are such that light is emitted from the edges when a light source 6 contained within a cavity 4 is switched on. The panel 2 may have rounded or bevelled edges around all or part of the perimeter. Additionally, an edge covering 14 may be provided around at least part of the perimeter of the light transmissive panel 2. This edge covering 14 may be opaque or translucent. Where the covering 14 is able to transmit light, it may be coloured or patterned to add to the aesthetic quality of the light emitting device 1. The edge covering could be chosen to contain fluorescent pigments. The chosen edge covering 14 may be made from vinyl, polyethylene, rubber or other suitable material.

To create a more diffuse light emission from the panel 2, further translucent layers 10 may be provided adjacent to one or both of the faces of the panel 2 to cover the surface treatment or patterning 8, as shown in FIG. 4. The translucent layers 10 may be attached to the faces of the light transmissive panel 2 or may form part of light transmitting sheets 12 placed over one or both faces of the panel 2.

The light transmitting sheets 12 comprise transparent or translucent material which permits the light from the panel 2 to pass through. The light transmitting sheets 12 may be coloured and may incorporate a graphic representation. The graphic representation may be in the form of an image or design or text and may be formed by regions of different coloured material or opaque material, printed areas on the surface of the sheets 12, or similar.

The light transmitting sheets 12 are attached to one or both faces of the light transmissive panel 2, as shown in FIG. 4. In embodiments in which only one light transmitting sheet is used, the other face of the panel 2 may be covered by an opaque board (not shown) to block any light emitted from that face of the panel.

In certain embodiments of the invention, additional blocking layers 16 may be provided between the light transmissive panel 2 and the light transmitting sheets 12, immediately adjacent to the light source 6, as shown in FIG. 4. These layers act to limit or block the amount of light emitted by the light source 6 that passes directly through the light transmitting sheets 12 which would otherwise create an area of increased brightness in the device. This blocking region may be provided on the surface of the panel 2 or may be provided by a printed area on a face of a light transmitting sheet 12, or similar.

In the embodiments shown in the figures, the light transmissive panel 2 and the light transmitting sheets 12 are substantially planar. However, it would also be possible for the light transmitting sheets 12 to be curved and attached to a planar light transmissive panel 2, or for both the panel 2 and the sheets 12 to be curved in a complementary manner such that faces of the panel 2 and sheets 12 come into contact over the majority of the area of the faces. The panel 2 and sheets 12 may be curved using any conventional forming means, such as thermoforming.

In embodiments of the invention including light transmitting sheets 12, the edge covering 14 may be arranged to cover (14a) or enclose (14b) the perimeter of both the light transmissive panel 2 and light transmitting sheets 12.

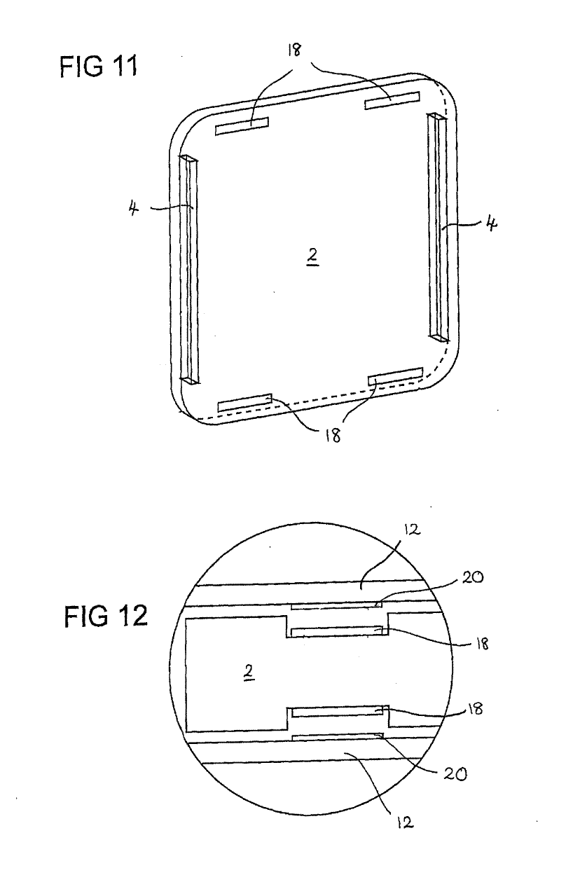

In one embodiment of the invention, the light transmitting sheets 12 are attached to the light transmissive device 1 by magnetic plates 18. As shown in FIGS. 11 and 12, magnetic plates 18 are located at various points on the faces of the panel 2, and suitable metal plates 20 are provided in corresponding positions on one face of the light transmitting sheets 12, so that the magnetic plates 18 and metal plates 20 come into contact when the light transmitting sheets 12 are placed in the correct position in relation to the light transmissive panel 2. Other means of attachment may also be used such as screws, clips, adhesives or similar.

Therefore, embodiments of this invention provide a backlit lighting device and a compact and slim display. The incorporation of a light source in a cavity within the panel of the light-emitting device is an improvement over previous edge-lit displays as a separate light enclosure is not required. Furthermore, the light-emitting device allows light to be emitted both from the centre of the display and from the edges. The edges may have illuminated light in any colour; the colour given by either of the colour filter applied to a cavity close to the edge, the edge covering or the colour of the light source embedded in the cavity of the central panel.

1. A light-emitting device comprising a panel having a cavity for housing at least one light source, the panel having edges and two major surfaces such that light emitted from at least one light source in the cavity propagating along the panel will be substantially internally reflected; and a patterning or surface treatment on at least one major surface providing regions to allow some light to be emitted from that surface, such that light will be emitted substantially evenly across said surface of the panel; wherein said at least one major surface is covered partially or wholly with a light-transmitting sheet incorporating a graphic representation, and wherein the colour of light emitted from the edges of the panel will be determined by the colour of the light source in the cavity.

2. A light-emitting device as claimed in claim 1, wherein a light filter such as vinyl or ink is disposed in an empty cavity thus affecting the colour of the light emitted from the edges close to that cavity.

3. A light-emitting device as claimed in claim 1, wherein a reflection strip is disposed in one or more cavities.

4. A light-emitting device as claimed in claim 1, wherein a translucent edge covering is provided around all or some of the perimeter of the panel by application of ink or otherwise and will determine the colour of light emitted from the edges.

5. A light-emitting device as claimed in claim 1, wherein a translucent layer is provided on at least one major surface of the panel to create a more diffuse light emission.

6. A light-emitting device as claimed in claim 1, wherein the panel further comprises one or more empty cavities that will reflect at least some light propagating along the panel.

7. A light-emitting device as claimed claim 1, wherein two light sources are housed within a cavity, one directed into the centre of the panel, a second directed towards the edge of the panel.

8. A light-emitting device as claimed in claim 6, wherein the two light sources are of different colours.

9. A light-emitting device as claimed in claim 1, wherein at least one blocking layer is provided on the surface of the panel adjacent to a light source to limit the amount of light emitted from the surface of the panel.

10. A light-emitting device as claimed in claim 1, wherein the or each light transmitting sheet is attached to the panel by means of magnets.

11. A light-emitting device as claimed in claim 1, wherein the or each light transmitting sheet is curved.

12. A light-emitting device as claimed in claim 1, wherein the light transmissive panel is curved.

13. A light-emitting device as claimed in claim 1, wherein the edge is bevelled.

14. A light-emitting device as claimed in claim 1, wherein each major surface is provided with a patterning or surface treatment, providing regions to allow some light to be emitted from those surfaces, such that light will be emitted substantially evenly across said surfaces of the panel;
and wherein each major surface is covered partially or wholly with a light-transmitting sheet incorporating a graphic representation.

15. A light-emitting device comprising:
a panel having a cavity for housing a light source, the panel having surfaces such that light emitted from a light source in the cavity propagating along the panel will be substantially totally internally reflected;
a patterning or surface treatment on at least one major surface of the panel providing regions to allow some light to be emitted from that surface, such that light will be emitted substantially evenly across said surface of the panel;
at least one light source housed within a cavity;
one or more empty cavities that at least substantially reflect light propagating along the panel;
at least one light transmitting sheet incorporating a graphic representation; and
magnetic plates on the surface of the panel and metal plates on said light transmitting sheet, for attaching the light transmitting sheet to the panel.

16. A method for manufacturing a light-emitting device, comprising the steps of:
applying patterning or surface treatment to at least one surface of a light transmissive panel, so that light propagating along the panel that would otherwise be totally internally reflected is emitted from the surface of the panel in the regions of the patterning or surface treatment;
creating at least one cavity within the panel to house a light source; and
attaching at least one light transmitting sheet to one or more surfaces of the panel; such that when a light source is placed in the cavity and switched on, light is emitted substantially evenly across said surface of the panel and passes through said light transmitting sheet.
